(19) United States
(12) Patent Application Publication
(10) Pub. No.: US 2024/0379828 A1
(43) Pub. Date: Nov. 14, 2024

(54) METHOD OF MANUFACTURING SEMICONDUCTOR DEVICES

(71) Applicant: Samsung Electronics Co., Ltd., Suwon-si (KR)

(72) Inventor: Taeyoung Kim, Suwon-si (KR)

(21) Appl. No.: 18/586,833

(22) Filed: Feb. 26, 2024

(30) Foreign Application Priority Data
May 10, 2023 (KR) 10-2023-0060205

(51) Int. Cl. H01L 29/66; H01L 21/02; H01L 21/28; H10B 51/40

(52) U.S. Cl. CPC H01L 29/6684; H01L 21/02483; H01L 21/28035; H10B 51/40

(57) ABSTRACT

In a method of manufacturing a semiconductor device, a ferroelectric layer may be formed on a first region of a substrate, the substrate including the first region and a second region. A gate insulation layer may be formed on and contacting an upper surface of the ferroelectric layer and on an upper surface of the second region of the substrate. A first conductive layer and a second conductive layer may be sequentially stacked on the gate insulation layer. The second conductive layer and the first conductive layer may be patterned to form first and second gate electrode structures on the first and second regions, respectively, of the substrate.

### CROSS-REFERENCE TO RELATED APPLICATION

This application claims priority under 35 U.S.C. § 119 to Korean Patent Application No. 10-2023-0060205, filed on May 10, 2023 in the Korean Intellectual Property Office (KIPO), the disclosure of which is incorporated by reference herein in its entirety.

### TECHNICAL FIELD

Example embodiments of the inventive concept relate to a method of manufacturing a semiconductor device.

### DISCUSSION OF RELATED ART

In a method of manufacturing an embedded memory device including both a memory device and a logic device, a first transistor for logic circuits is formed on a logic region of a substrate, and a second transistor for memory circuits is formed on a memory region of the substrate. As the first and second transistors are formed on the logic region and the memory region, respectively, of the substrate by separate processes, the processes may be complicated and the cost of the processes may increase.

### SUMMARY

Example embodiments of the inventive concept provide a method of manufacturing a semiconductor device having enhanced electric characteristics.

According to example embodiments of the inventive concept, there is provided a method of manufacturing a semiconductor device. In the method, a ferroelectric layer may be formed on a first region of a substrate, the substrate including the first region and a second region. A gate insulation layer may be formed on and contacting an upper surface of the ferroelectric layer and an upper surface of the second region of the substrate. A first conductive layer and a second conductive layer may be sequentially stacked on the gate insulation layer. The second conductive layer and the first conductive layer may be patterned to form first and second gate electrode structures on the first and second regions, respectively, of the substrate.

According to example embodiments of the inventive concept, there is provided a method of manufacturing a semiconductor device. In the method, an upper portion of a first region of a substrate including the first region and a second region may be removed to form a recess. A preliminary ferroelectric layer may be formed on the first and second regions of the substrate to at least partially fill the recess. A heat treatment process may be performed on the substrate so that a portion of the preliminary ferroelectric layer on the first region of the substrate may be converted into a ferroelectric layer. The preliminary ferroelectric layer may be removed to expose an upper surface of the second region of the substrate. A gate insulation layer may be formed on the ferroelectric layer and the second region of the substrate. First and second gate electrode structures may be formed on the first and second regions, respectively, of the substrate.

According to example embodiments of the inventive concept, there is provided a method of manufacturing a semiconductor device. In the method, an upper portion of a first region of a substrate including the first region and a second region may be removed to form a recess. A preliminary ferroelectric layer may be formed on the first and second regions of the substrate to at least partially fill the recess. A stress aggressor may be formed on a portion of the preliminary ferroelectric layer on the first region of the substrate. A heat treatment process may be per formed on the substrate so that a portion of the preliminary ferroelectric layer under the stress aggressor may be converted into a ferroelectric layer. A planarization process may be performed on the preliminary ferroelectric layer to expose an upper surface of the second region of the substrate. A gate insulation layer may be formed on the ferroelectric layer and the second region of the substrate. First and second gate electrode structures may be formed on the first and second regions, respectively, of the substrate.

In the method of manufacturing the semiconductor device, the gate insulation patterns, which may be elements of the FeFET and the MOSFET on the memory region and the logic region, respectively, of the substrate, may be formed not by separate processes but by the same process. Additionally, the gate electrode structures, which may be elements of the FeFET and the MOSFET, respectively, may also be formed not by separate processes but by the same process. Thus, the manufacturing processes of the semiconductor device including the FeFET and the MOSFET may be simplified and the cost of the manufacturing processes may be reduced.

### BRIEF DESCRIPTION OF THE DRAWINGS

FIG. 1 is a plan view illustrating regions of a substrate on which a semiconductor device is formed in accordance with example embodiments.

FIGS. 2 to 8 are cross-sectional views illustrating a method of manufacturing the semiconductor device in accordance with example embodiments.

FIGS. 9 and 10 are cross-sectional views illustrating a method of manufacturing a semiconductor device in accordance with example embodiments.

FIGS. 11 and 12 are cross-sectional views illustrating a method of manufacturing a semiconductor device in accordance with example embodiments.

### DETAILED DESCRIPTION OF THE EMBODIMENTS

The above and other features of aspects of the inventive concept will be more clearly understood by describing in detail exemplary embodiments thereof with reference to the accompanying drawings.

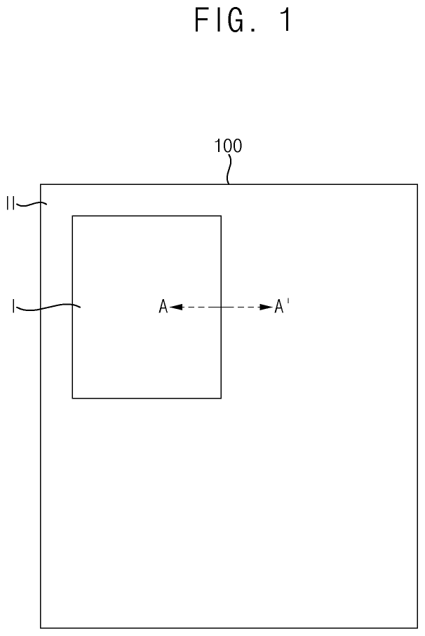

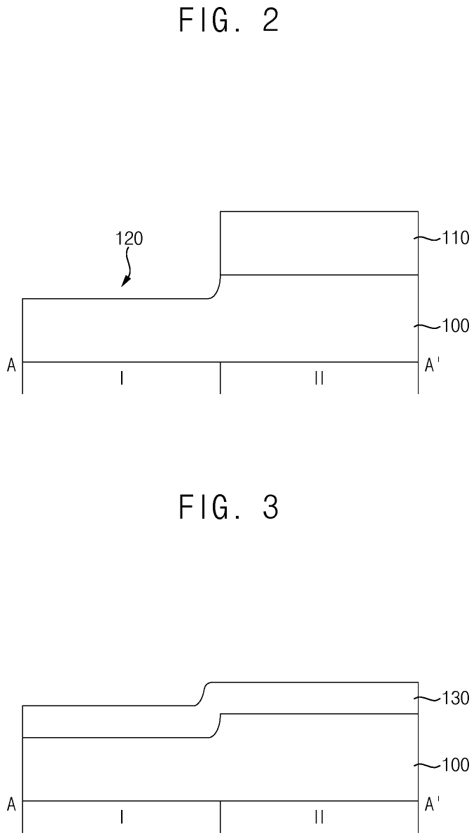

FIG. 1 is a plan view illustrating regions of a substrate on which a semiconductor device is formed in accordance with example embodiments, and FIGS. 2 to 8 are cross-sectional views illustrating a method of manufacturing the semiconductor device in accordance with example embodiments. Particularly, FIGS. 2 to 8 are cross-sectional views taken along line A-A′ of FIG. 1.

Referring to FIG. 1, a substrate 100 may include first and second regions I and II, and may further include a third region.

In example embodiments, the first region I of the substrate 100 may be a first memory region on which a non-volatile memory device, e.g., a FeRAM, a flash memory device, etc., is formed, and the second region II of the substrate 100 may be a logic region on which a logic device is formed. Although not illustrated, the substrate 100 may include a third region on which a volatile memory device, e.g., a DRAM device is formed. The semiconductor device may be an embedded memory device including the logic device, the non-volatile memory device, and the volatile memory device.

Hereinafter, only the logic device and the memory device to be formed on the first and second regions I and II, respectively, of the substrate 100 are described. The memory device to be formed on the third region of the substrate 100 is not described herein.

Referring to FIG. 2, a first mask 110 may be formed on the second region II of the substrate 100, and an upper portion of the substrate 100 may be removed by an etching process using the first mask 110 as an etching mask.

The substrate 100 may include a semiconductor material, e.g., silicon, germanium, silicon-germanium, etc., or a III-V group compound semiconductor, such as GaP, GaAs, GaSb, etc. In an example embodiment, the substrate 100 may be a silicon-on-insulator (SOI) substrate or a germanium-on-insulator (GOI) substrate.

The first mask 110 may include or may be formed of a photoresist pattern or a hard mask including an insulating nitride, e.g., silicon nitride. As the etching process is performed, a recess 120 may be formed on the first region I of the substrate 100.

Referring to FIG. 3, the first mask 110 may be removed, and a preliminary ferroelectric layer 130 may be formed on the first and second regions I and II of the substrate 100 to fill the recess 120.

In example embodiments, the preliminary ferroelectric layer 130 may be conformally formed on the substrate 100, and thus an upper surface of a portion of the preliminary ferroelectric layer 130 on the second region II of the substrate 100 may be higher than an upper surface of a portion of the preliminary ferroelectric layer 130 on the first region I of the substrate 100. Alternatively, the upper surface of the portion of the preliminary ferroelectric layer 130 on the second region II of the substrate 100 may be lower than or substantially coplanar with the upper surface of the portion of the preliminary ferroelectric layer 130 on the first region I of the substrate 100. Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

In an example embodiment, the preliminary ferroelectric layer 130 may include or may be formed of a ferroelectric material, e.g., a perovskite material such as BaTiOₓ, a hafnium-based fluorite material, or hafnium zirconium oxide (HfₓZr₁₋ₓO_{y}).

In an example embodiment, the preliminary ferroelectric layer 130 may include or may be formed of an anti-ferroelectric material, e.g., zirconium oxide (ZrO₂), hafnium zirconium oxide (HfₓZr₁₋ₓO_{y}), lead zirconate (PbZrO₃), sodium niobate (NaNbO₃), etc.

In an example embodiment, the preliminary ferroelectric layer 130 may include or may be formed of a ferroelectric material or an anti-ferroelectric material doped with aluminum (Al), barium (Ba), silicon (Si), yttrium (Y), scandium (Sc), strontium (Sr), etc.

In an example embodiment, the preliminary ferroelectric layer 130 may include or may be formed of a ferroelectric material or an anti-ferroelectric material doped with a lanthanum-based rare earth element.

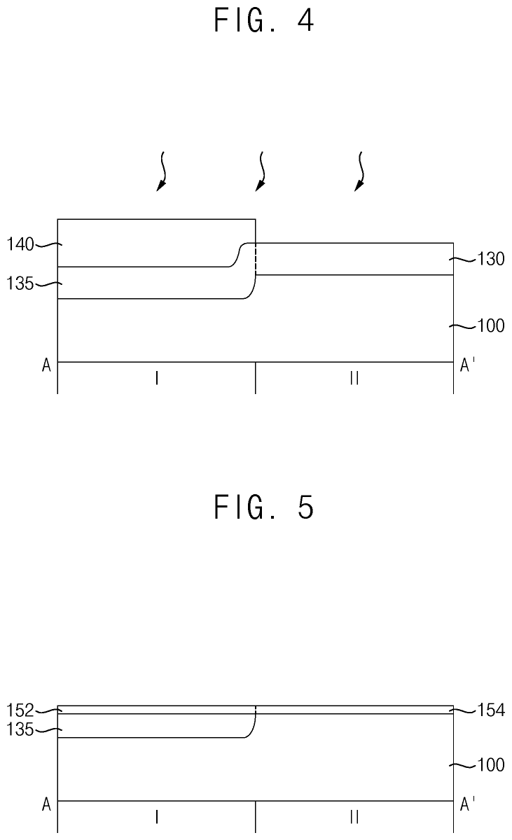

Referring to FIG. 4, a stress aggressor 140 may be formed on a portion of the preliminary ferroelectric layer 130 on the first region I of the substrate 100, and a heat treatment process, e.g., an annealing process may be performed on the substrate 100 having the preliminary ferroelectric layer 130 and the stress aggressor 140 thereon.

The stress aggressor 140 may include or may be formed of a metal, e.g., tungsten, molybdenum, etc. As the heat treatment process is performed, the stress aggressor 140 may apply a mechanical stress on the preliminary ferroelectric layer 130, and thus the ferroelectric characteristics of the portion of the preliminary ferroelectric layer 130 on the first region I of the substrate 100 may be strengthen to be converted into a ferroelectric layer 135.

Referring to FIG. 5, the stress aggressor 140 may be removed, and the portion of the preliminary ferroelectric layer 130 on the second region II of the substrate 100 may be removed to expose an upper surface of the second region II of the substrate 100.

In example embodiments, a planarization process may be performed on the preliminary ferroelectric layer 130 and the ferroelectric layer 135 until the upper surface of the second region II of the substrate 100 is exposed. The planarization process may include a chemical mechanical polishing (CMP) process and/or an etch back process.

As the planarization process is performed, the preliminary ferroelectric layer 130 on the second region II of the substrate 100 and an upper portion of the ferroelectric layer 135 on the first region I of the substrate 100 may be removed. In example embodiments, an upper surface of the ferroelectric layer 135 on the first region I of the substrate 100 may be substantially coplanar with the upper surface of the second region II of the substrate 100.

Alternatively, a second mask may be formed on the first region I of the substrate 100, and an etching process may be performed using the second mask as an etching mask to remove the preliminary ferroelectric layer 130 on the second region II of the substrate 100.

A gate insulation layer may be formed on the upper surface of the ferroelectric layer 135 and the upper surface of the second region II of the substrate 100. The gate insulation layer may include or may be formed of an oxide, e.g., silicon oxide.

Hereinafter, a portion of the gate insulation layer on the first region I of the substrate 100 may be referred to as a first gate insulation pattern 152, and a portion of the gate insulation layer on the second region II of the substrate 100 may be referred to as a second gate insulation pattern 154.

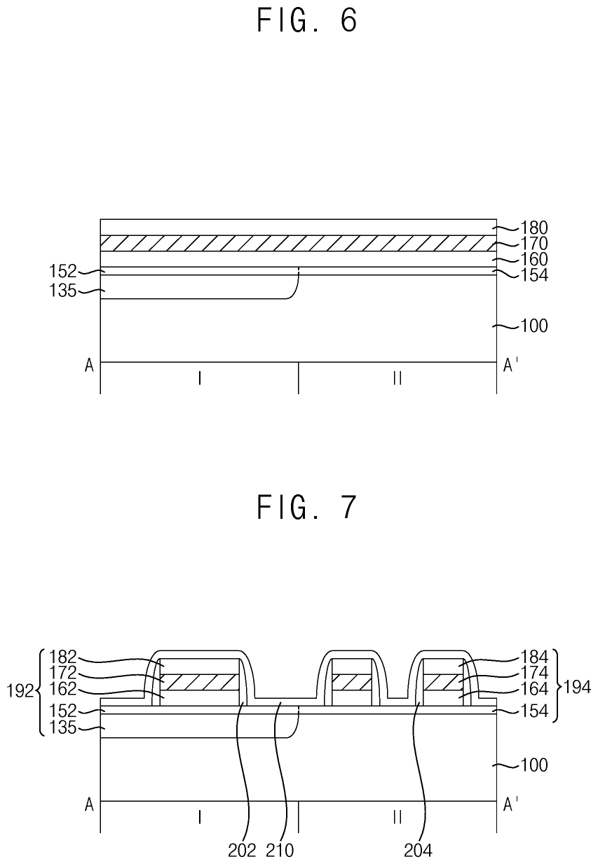

Referring to FIG. 6, a first conductive layer 160, a second conductive layer 170 and a gate mask layer 180 may be sequentially stacked on the first and second gate insulation patterns 152 and 154.

The first conductive layer 160 may include or may be formed of, e.g., doped polysilicon, the second conductive layer 170 may include or may be formed of, e.g., a metal, a metal nitride, a metal silicide, etc., and the gate mask layer 180 may include or may be formed of an insulating nitride, e.g., silicon nitride.

Referring to FIG. 7, the gate mask layer 180, the second conductive layer 170 and the first conductive layer 160 may be patterned to form a first gate electrode structure including a first conductive pattern 162, a third conductive pattern 172 and a first gate mask 182 sequentially stacked on the first region I of the substrate 100, and to form a second gate electrode structure including a second conductive pattern 164, a fourth conductive pattern 174 and a second gate mask 184 sequentially stacked on the second region II of the substrate 100.

The ferroelectric layer 135, the first gate insulation pattern 152 and the first gate electrode structure sequentially stacked on the first region I of the substrate 100 may collectively form a first gate structure 192. The second gate insulation pattern 154 and the second gate electrode structure sequentially stacked on the second region II of the substrate 100 may collectively form a second gate structure 194.

A spacer layer may be formed on the first and second gate electrode structures and the first and second gate insulation patterns 152 and 154, and may be anisotropically etched to form first and second gate spacers 202 and 204 on respective sidewalls of the first and second gate electrode structures. Each of the first and second gate spacers 202 and 204 may include or may be formed of an oxide, e.g., silicon oxide.

For example, an ion implantation process may be performed to form a first source/drain region on a portion of the first region I of the substrate 100 adjacent to the first gate electrode structure and the first gate spacer 202, and to form a second source/drain region on a portion of the second region II of the substrate 100 adjacent to the second gate electrode structure and the second gate spacer 204.

Thus, a first transistor including the first gate structure 192 and the first source/drain region may be formed on the first region I of the substrate 100, and a second transistor including the second gate structure 194 and the second source/drain region may be formed on the second region II of the substrate 100. In example embodiments, the first transistor may be a ferroelectric field effect transistor (FeFET), which may be an element of a FERAM device. Additionally, the second transistor may be a metal oxide semiconductor field effect transistor (MOSFET), which may be an element of a logic device.

An etch stop layer 210 may be formed on the first and second gate electrode structures, the first and second gate spacers 202 and 204, and the first and second gate insulation patterns 152 and 154. The etch stop layer 210 may include or may be formed of an insulating nitride, e.g., silicon nitride.

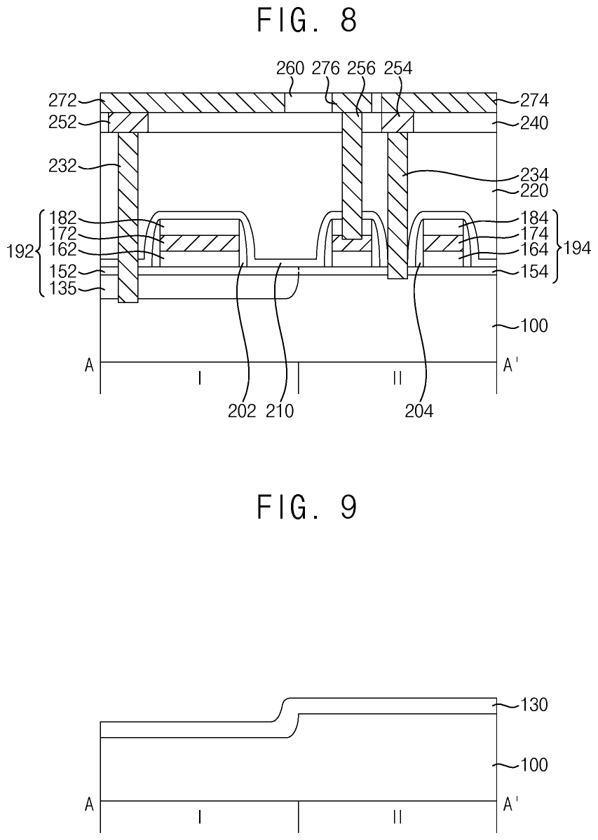

Referring to FIG. 8, a first insulating interlayer 220 may be formed on the etch stop layer 210. A first contact plug 232 extending through the first insulating interlayer 220, the etch stop layer 210, the first gate insulation pattern 152 and the ferroelectric layer 135 to contact the upper surface of the first region I of the substrate 100 may be formed, and a second contact plug 234 extending through the first insulating interlayer 220, the etch stop layer 210 and the second gate insulation pattern 154 to contact the upper surface of the second region II of the substrate 100 may also be formed.

In an example embodiment, a lower surface of the first contact plug 232 may be lower than a lower surface of the second contact plug 234.

A second insulating interlayer 240 may be formed on the first insulating interlayer 220 and the first and second contact plugs 232 and 234. First and second wirings 252 and 254 may be formed through the second insulating interlayer 240 and may contact upper surfaces of the first and second contact plugs 232 and 234, respectively. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

Additionally, a third contact plug 256 extending through the second insulating interlayer 240, the first insulating interlayer 220, the etch stop layer 210 and the second gate mask 184 to contact an upper surface of the fourth conductive pattern 174 may be formed on the second region II of the substrate 100.

A third insulating interlayer 260 may be formed on the second insulating interlayer 240, the first and second wirings 252 and 254 and the third contact plug 256. Third wiring 272, fourth wiring 274 and fifth wiring 276 may be formed so as to extend through the third insulating interlayer 260 to contact upper surfaces of the first wiring 252, the second wiring 254 and the third contact plug 256, respectively.

The layouts of the first to third contact plugs 232, 234 and 256, and the first to fifth wirings 252, 254, 272, 274 and 276 on the first and second regions I and II of the substrate 100 may not be limited to that of FIG. 8, and the levels and numbers thereof may be various.

Each of the first to third insulating interlayers 220, 240 and 260 may include or may be formed of an oxide, e.g., silicon oxide, and each of the first to third contact plugs 232, 234 and 256 and the first to fifth wirings 252, 254, 272, 274 and 276 may include or may be formed of a conductive material, e.g., a metal, a metal nitride, a metal silicide, etc.

The semiconductor device may be manufactured by the above processes.

As described above, the recess 120 may be formed on the first region I of the substrate 100, the preliminary ferroelectric layer 130 may be formed on the first and second regions I and II of the substrate 100 to fill the recess 120, the portion of the preliminary ferroelectric layer 130 on the first region I of the substrate 100 may be converted into the ferroelectric layer 135, the portion of the preliminary ferroelectric layer 130 on the second region II of the substrate 100 may be removed, the gate insulation layer may be formed on the first and second regions I and II of the substrate 100, the first and second gate electrodes 192 and 194 may be formed on the first and second regions I and II, respectively, of the substrate 100, and the first and second source/drain regions may be formed on the first and second regions I and II, respectively, of the substrate 100.

Thus, the FeFET and the MOSFET, which may be elements of the FeRAM device and the logic device, respectively, may be formed on the first and second regions I and II, respectively, of the substrate 100. Additionally, the first and second gate insulation patterns 152 and 154, which may be elements of the FeFET and the MOSFET, respectively, may be formed on the first and second regions I and II, respectively, of the substrate 100 by the same process, and the first and second gate electrode structures, which may be elements of the FeFET and the MOSFET, respectively, may also be formed on the first and second regions I and II, respectively, of the substrate 100 by the same process.

That is, even though the first and second gate structures 192 and 194 included in the FeFET and the MOSFET, respectively, do not have the same stack structure, the first and second gate insulation patterns 152 and 154 included in the first and second gate structures 192 and 194, respectively, may be simultaneously formed by forming the gate insulation layer, and the first and second gate electrode structures included in the first and second gate structures 192 and 194, respectively, may also be simultaneously formed by forming and patterning the first conductive layer, the second conductive layer and the gate mask layer.

Thus, when compared to the formation of the FeFET and the MOSFET on the first and second regions I and II, respectively, of the substrate 100 by separate processes, the manufacturing processes of the semiconductor device including the FeFET and the MOSFET may be simplified and the cost of the manufacturing processes may be reduced.

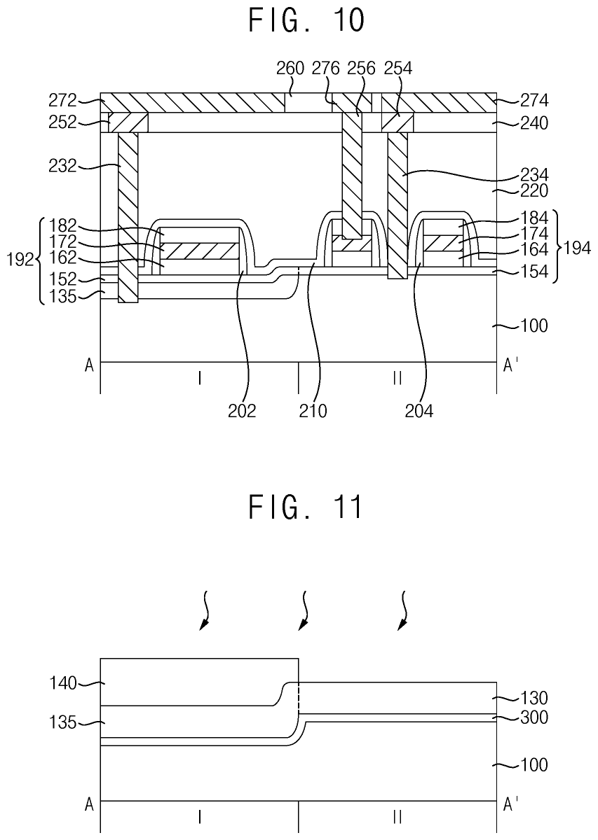

FIGS. 9 and 10 are cross-sectional views illustrating a method of manufacturing a semiconductor device in accordance with example embodiments, which may correspond to FIGS. 3 and 8, respectively.

This method may include processes substantially the same as or similar to those illustrated with reference to FIGS. 1 to 8, and thus repeated explanations thereof are omitted herein.

Referring to FIG. 9, processes substantially the same as or similar to those illustrated with reference to FIGS. 1 to 3 may be performed to form the preliminary ferroelectric layer 130.

However, the preliminary ferroelectric layer 130 may not entirely fill the recess 120, and thus the upper surface of the preliminary ferroelectric layer 130 on the first region I of the substrate 100 may be lower than the upper surface of the second region II of the substrate 100, except for a portion of the preliminary ferroelectric layer 130 adjacent to the second region II of the substrate 100.

Processes substantially the same as or similar to those illustrated with reference to FIGS. 4 and 5 may be performed. However, as the portion of the preliminary ferroelectric layer 130 on the second region II of the substrate 100 is removed, the upper surface of the ferroelectric layer 135 remaining on the first region I of the substrate 100 may be lower than the upper surface of the second region II of the substrate 100, except for a portion of the ferroelectric layer 135 adjacent to the second region II of the substrate 100.

Referring to FIG. 10, processes substantially the same as or similar to those illustrated with reference to FIGS. 6 to 8 may be performed to complete the fabrication of the semiconductor device.

In example embodiments, upper surfaces of the first gate insulation pattern 152 and the first gate electrode structure on the first region I of the substrate 100 may be lower than upper surfaces of the second gate insulation pattern 154 and the second gate electrode structure on the second region II of the substrate 100.

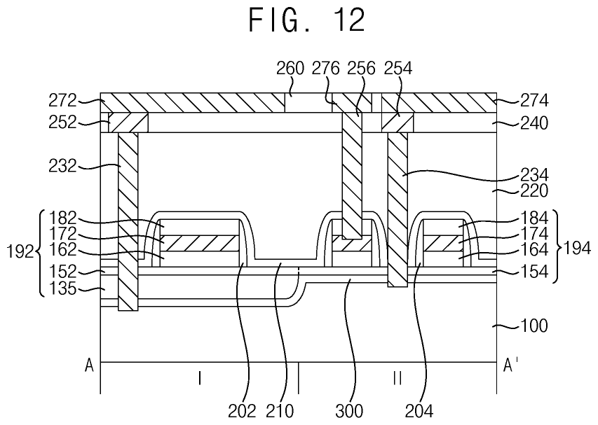

FIGS. 11 and 12 are cross-sectional views illustrating a method of manufacturing a semiconductor device in accordance with example embodiments, which may correspond to FIGS. 4 and 8, respectively.

This method may include processes substantially the same as or similar to those illustrated with reference to FIGS. 1 to 8, and thus repeated explanations thereof are omitted herein.

Referring to FIG. 11, processes substantially the same as or similar to those illustrated with reference to FIGS. 1 to 4 may be performed to form the preliminary ferroelectric layer 130 so that the portion of the preliminary ferroelectric layer 130 on the first region I of the substrate 100 may be converted into the ferroelectric layer 135.

However, during the heat treatment process, an oxide layer 300 including, e.g., silicon oxide may be additionally formed between the upper surface of the substrate 100 and the preliminary ferroelectric layer 130.

Referring to FIG. 12, processes substantially the same as or similar to those illustrated with reference to FIGS. 5 to 8 may be performed to complete the fabrication of the semiconductor device.

In example embodiments, the oxide layer 300 may be formed between the upper surface of the first region I of the substrate 100 and the ferroelectric layer 135, and between the upper surface of the second region II of the substrate 100 and the second gate insulation pattern 154.

While aspects of the inventive concept have been shown and described with reference to exemplary embodiments thereof, it will be apparent to those of ordinary skill in the art that various modifications in form and details may be made thereto without departing from the spirit and scope of the following claims.

What is claimed is:

1. A method of manufacturing a semiconductor device, the method comprising:
forming a ferroelectric layer on a first region of a substrate, the substrate including the first region and a second region;
forming a gate insulation layer on and contacting an upper surface of the ferroelectric layer and on an upper surface of the second region of the substrate;
sequentially stacking a first conductive layer and a second conductive layer on the gate insulation layer; and
patterning the second conductive layer and the first conductive layer to form first and second gate electrode structures on the first and second regions, respectively, of the substrate.

2. The method of claim 1, wherein forming the ferroelectric layer on the first region of a substrate includes:
forming a preliminary ferroelectric layer on the first and second regions of the substrate; and
removing a portion of the preliminary ferroelectric layer on the second region of the substrate.

3. The method of claim 2, further comprising, after forming the preliminary ferroelectric layer on the first and second regions of the substrate:
forming a stress aggressor on the first region of the substrate; and
performing a heat treatment process on the substrate having the stress aggressor and the preliminary ferroelectric layer thereon so that a portion of the preliminary ferroelectric layer on the first region of the substrate is converted into the ferroelectric layer.

4. The method of claim 3, wherein an oxide layer is formed between the substrate and the preliminary ferroelectric layer as the heat treatment process is performed.

5. The method of claim 3, wherein the stress aggressor includes tungsten or molybdenum.

6. The method of claim 2, further comprising, prior to forming the preliminary ferroelectric layer on the first and second regions of the substrate:
removing an upper portion of the first region of the substrate to form a recess,
wherein the preliminary ferroelectric layer is formed on the first and second regions of the substrate, and at least partially fills the recess.

7. The method of claim 6, wherein removing a portion of the preliminary ferroelectric layer on the second region of the substrate includes performing a planarization process on the preliminary ferroelectric layer.

8. The method of claim 6, wherein an upper surface of a portion of the preliminary ferroelectric layer in the recess is higher than or substantially coplanar with the upper surface of the second region of the substrate.

9. The method of claim 6, wherein an upper surface of a remaining portion of the preliminary ferroelectric layer in the recess, except for a portion of the preliminary ferroelectric layer adjacent to the second region of the substrate, is lower than the upper surface of the second region of the substrate.

10. The method of claim 1, wherein the first conductive layer includes doped polysilicon, and the second conductive layer includes a metal, a metal nitride or a metal silicide.

11. The method of claim 1, wherein the first region of the substrate is a memory region on which a memory device is formed, and the second region of the substrate is a logic region on which a logic device is formed.

12. A method of manufacturing a semiconductor device, the method comprising:
removing an upper portion of a first region of a substrate to form a recess, the substrate including the first region and a second region;
forming a preliminary ferroelectric layer on the first and second regions of the substrate to at least partially fill the recess;
performing a heat treatment process on the substrate so that a portion of the preliminary ferroelectric layer on the first region of the substrate is converted into a ferroelectric layer;
removing the preliminary ferroelectric layer to expose an upper surface of the second region of the substrate;
forming a gate insulation layer on the ferroelectric layer and the second region of the substrate; and
forming first and second gate electrode structures on the first and second regions, respectively, of the substrate.

13. The method of claim 12, further comprising, after forming the preliminary ferroelectric layer on the first and second regions of the substrate:
forming a stress aggressor on the first region of the substrate.

14. The method of claim 12, wherein removing the preliminary ferroelectric layer includes performing a planarization process on the preliminary ferroelectric layer.

15. The method of claim 12, wherein an upper surface of a portion of the preliminary ferroelectric layer in the recess is higher than or substantially coplanar with the upper surface of the second region of the substrate.

16. The method of claim 12, wherein an upper surface of a remaining portion of the preliminary ferroelectric layer in the recess, except for a portion of the preliminary ferroelectric layer adjacent to the second region of the substrate, is lower than the upper surface of the second region of the substrate.

17. The method of claim 12, wherein forming the first and second gate electrode structures on the first and second regions, respectively, of the substrate includes:
sequentially stacking a first conductive layer and a second conductive layer on the gate insulation layer; and
patterning the second conductive layer and the first conductive layer to form the first and second gate electrode structures on the first and second regions, respectively, of the substrate.

18. The method of claim 12, wherein the first region of the substrate is a memory region on which a memory device is formed, and the second region of the substrate is a logic region on which a logic device is formed.

19. A method of manufacturing a semiconductor device, the method comprising:
removing an upper portion of a first region of a substrate to form a recess, the substrate including the first region and a second region;
forming a preliminary ferroelectric layer on the first and second regions of the substrate to at least partially fill the recess;
forming a stress aggressor on a portion of the preliminary ferroelectric layer on the first region of the substrate;
performing a heat treatment process on the substrate so that a portion of the preliminary ferroelectric layer under the stress aggressor is converted into a ferroelectric layer;
performing a planarization process on the preliminary ferroelectric layer to expose an upper surface of the second region of the substrate;
forming a gate insulation layer on the ferroelectric layer and the second region of the substrate; and
forming first and second gate electrode structures on the first and second regions, respectively, of the substrate.

20. The method of claim 19, wherein an upper surface of a portion of the preliminary ferroelectric layer in the recess is higher than or substantially coplanar with the upper surface of the second region of the substrate.
